(19) United States
(12) Patent Application Publication
(10) Pub. No.: US 2015/0226385 A1
(43) Pub. Date: Aug. 13, 2015

(54) Systems and Methods for Application of Coatings Including Thixotropic Agents onto Optical Elements, and Optical Elements Having Coatings Including Thixotropic Agents

(71) Applicant: Cree, Inc., Durham, NC (US)

(72) Inventors: Peter S. Andrews, Durham, NC (US); Jack T. Vu, Raleigh, NC (US)

(73) Assignee: Cree, Inc., Durham, NC (US)

(21) Appl. No.: 14/177,839

(22) Filed: Feb. 11, 2014

(51) Int. Cl. F21K 99/00; F21V 9/16; B05D 1/02; H01L 33/50

(52) U.S. Cl. CPC F21K 9/56; H01L 33/507; F21V 9/16; B05D 1/02; F21Y 2101/02

(57) ABSTRACT

A method of forming an optical device includes providing an optical element, providing a luminescent suspension including a liquid encapsulant material, phosphor particles, a solvent and a thixotropic agent, atomizing the luminescent suspension, and spraying the atomized luminescent suspension onto the optical element using a flow of pressurized gas. A light emitting structure includes an optical element configured to emit light upon energization thereof, and a thin phosphor layer including a thixotropic agent on the optical element.

### BACKGROUND

This invention relates to coating of semiconductor devices. In particular, this invention relates to the application of optical materials to optical elements. In particular embodiments, the invention relate to the application of optical coatings, such as phosphors and/or other particles, to optical elements of a semiconductor based light emitting device, such as light emitting diode based devices. In yet other embodiments, the invention relates to spraying optical elements with phosphor and/or other particles.

Light emitting diodes (LEDs) are semiconductor devices that convert electric energy to light. Inorganic LEDs typically include an active layer of semiconductor material formed between two oppositely doped layers. When a bias is applied across the active region, holes and/or electrons are injected into the active region. Recombination of holes and electrons in the active region generates light that can be emitted from the LED. The active region may include a single and/or double hetero junction, quantum well, or multiple quantum well structures with corresponding barrier layers and may include other layers. The structure of the device, and the material from which it is constructed, determine the intensity and wavelength of light emitted by the device. Recent advances in LED technology have resulted in highly efficient solid-state light sources that surpass the efficiency of incandescent and halogen light sources, providing light with equal or greater brightness in relation to input power.

Conventional LEDs generate narrow bandwidth, essentially monochromatic light. However, it is desirable to generate polychromatic light, such as white light, using solid state light sources. One way to produce white light from conventional LEDs is to combine different wavelengths of light from different LEDs. For example, white light can be produced by combining the light from red, green and blue emitting LEDs, or combining the light from blue and amber LEDs. This approach, however, requires the use of multiple LEDs to produce a single color of light, which can potentially increase the overall cost, size, complexity and/or heat generated by such a device. In addition, the different colors of light may also be generated from different types of LEDs fabricated from different material systems. Combining different LED types to form a white lamp can require costly fabrication techniques and can require complex control circuitry, since each device may have different electrical requirements and/or may behave differently under varied operating conditions (e.g. with temperature, current or time).

Light from a blue emitting LED has been converted to white light by surrounding the LED with a yellow phosphor, such as cerium-doped yttrium aluminum garnet (Ce:YAG). The phosphor material absorbs and “downconverts” some of the blue light generated by the LED. That is, the phosphor material generates light, such as yellow light, in response to absorbing the blue light. Thus, some of the blue light generated by the LED is converted to yellow light. Some of the blue light from the LED passes through the phosphor without being changed, however. The overall LED/phosphor structure emits both blue and yellow light, which combine to provide light that is perceived as white light.

LEDs have been combined with phosphor layers by dispensing a volume of phosphor-containing encapsulant material (e.g., epoxy resin or silicone) over the LED to cover the LED. In these methods, however, it can be difficult to control the geometry and/or thickness of the phosphor layer. As a result, light emitted from the LED at different angles can pass through different amounts of conversion material, which can result in an LED with non-uniform color temperature as a function of viewing angle. Because the geometry and thickness is hard to control, it can also be difficult to consistently reproduce LEDs with the same or similar emission characteristics.

Another conventional method for coating an LED is by stencil printing. In a stencil printing approach, multiple light emitting semiconductor devices are arranged on a substrate with a desired distance between adjacent LEDs. The stencil is provided having openings that align with the LEDs, with the holes being slightly larger than the LEDs and the stencil being thicker than the LEDs. A stencil is positioned on the substrate with each of the LEDs located within a respective opening in the stencil. A composition is then deposited in the stencil openings, covering the LEDs, with a typical composition being a phosphor in a silicone polymer that can be cured by heat or light. After the holes are filled, the stencil is removed from the substrate and the stenciling composition is cured to a solid state.

Like the volumetric dispense method described above, the stenciling method may also present difficulties in controlling the geometry and/or layer thickness of the phosphor containing polymer. The stenciling composition may not fully fill the stencil opening, resulting in non-uniform layers. The phosphor-containing composition can also stick to the stencil opening, which may reduce the amount of composition remaining on the LED. These problems can result in LEDs having non-uniform color temperature and LEDs that are difficult to consistently reproduce with the same or similar emission characteristics.

Another conventional method for coating LEDs with a phosphor utilizes electrophoretic deposition (EPD). The conversion material particles are suspended in an electrolyte based solution. A plurality of LEDs are immersed in the electrolyte solution. One electrode from a power source is coupled to the LEDs, and the other electrode is arranged in the electrolyte solution. The bias from the power source is applied across the electrodes, which causes current to pass through the solution to the LEDs. This creates an electric field that causes the conversion material to be drawn to the LEDs, covering the LEDs with the conversion material.

After the LEDs are covered by the conversion material, they are removed from the electrolyte solution so that the LEDs and their conversion material can be covered by a protective resin. This adds an additional step to the process and the conversion material (phosphor particles) can be disturbed prior to the application of the epoxy. During the deposition process, the electric field in the electrolyte solution can also vary such that different concentrations of conversion material can be deposited across the LEDs. Additionally, the electric field in the electrolyte solution may act preferentially according to particle size thereby increasing the difficulty of depositing mixed phosphors of different particle sizes. The conversion particles can also settle in the solution, which can also result in different conversion material concentrations across the LEDs. The electrolyte solution can be stirred to prevent settling, but this presents the danger of disturbing the particles already on the LEDs.

Still another coating method for LEDs utilizes droplet deposition using systems similar to those in an ink-jet printing apparatus. Droplets of a liquid phosphor-containing material are sprayed from a print head. The phosphor-containing droplets are ejected from a nozzle on the print head in response to pressure generated in the print head by a thermal bubble and/or by piezoelectric crystal vibrations. However, in order to control the flow of the phosphor-containing composition from the ink-jet print head, it may be necessary for the print head nozzle to be relatively small. In fact, it may be desirable to engineer the size and/or shape of the phosphor particles to prevent them from catching in the nozzle and clogging the print head.

Problems with conventional methods of applying phosphor and/or other optical materials may include increased cost, complexity, clumping, dripping, settling, stratification, and/or separation, which may result in a reduced conformity and/or uniformity of the optical materials thus applied.

### SUMMARY

The present invention relates to an improvement in the application of optical materials, such as phosphor and/or other particles, to optical elements, such as light transmissive structures, reflectors, lens and/or the light emissive surface of a semiconductor light emitting device or other substrates or elements that interact with the emitted light. Some embodiments of the invention include spraying optical materials including thixotropic agents onto an optical element, such as a semiconductor light emitting device or other optical element(s) spaced from the semiconductor light emitting device.

A method according to some embodiments includes providing an optical element, providing a luminescent suspension including a liquid encapsulant material, phosphor particles, a solvent and a thixotropic agent, atomizing the luminescent suspension, and spraying the atomized luminescent suspension onto the optical element using a flow of pressurized gas.

The thixotropic agent may include fumed silica particles. In some embodiments, the thixotropic agent may include particles having a ratio of surface area per unit mass greater than about 100 m²/g.

The thixotropic agent may include particles having a concentration by weight to liquid encapsulant material in the luminescent suspension of less than about 1%.

The particles may include fumed silica particles, and a concentration by weight of the fumed silica particles to liquid encapsulant material in the luminescent suspension may be less than about 0.8%

The particles may include fumed silica particles, and a concentration by weight of the fumed silica particles to liquid encapsulant material in the luminescent suspension may be between about 0.5% and about 1.0%

A concentration by weight of the fumed silica particles to liquid encapsulant material in the luminescent suspension may be about 0.75%.

The phosphor particles may include a first plurality of phosphor particles configured to convert incident light to light having a first dominant wavelength and a second plurality of phosphor particles configured to convert incident light to light having a second dominant wavelength that is different from the first dominant wavelength.

The first phosphor particles may include red phosphor particles and the second phosphor particles may include green phosphor particles.

The first phosphor particles may have an average particle size that is smaller than an average particle size of the second phosphor particles.

The thixotropic agent may include agglomerated fumed silica particles having an average particle length between about 300 microns and 400 microns.

Spraying the luminescent suspension may include spraying the luminescent suspension with an air pressurized spray system.

Applying the layer of binder material may include spraying the binder material with an air pressurized spray system.

The luminescent suspension may include wavelength conversion particles suspended in a volatile solvent, the method further including evaporating a solvent from the luminescent suspension to provide a layer of wavelength conversion particles on the optical element.

The luminescent suspension may include wavelength conversion particles suspended in a nonvolatile solvent, the method further including curing the nonvolatile solvent to provide a layer including the wavelength conversion particles on the optical element.

The optical element may include an LED chip having a top surface and a wirebond pad on the top surface, and the method may further include bonding a wire to the wirebond pad before spraying the luminescent suspension onto the LED chip.

The optical element may include an LED wafer, and the method may further include singulating the LED wafer into a plurality of LED chips after applying the layer of binder material and after evaporating the solvent from the luminescent suspension.

Evaporating the solvent from the luminescent suspension may include baking the luminescent suspension and/or exposing the luminescent suspension to ultraviolet light.

The thixotropic agent may include fumed alumina or fumed titania.

The thixotropic agent may include a mixture of particles including fumed silica particles, fumed alumina particles and/or fumed titania particles.

The fumed silica particles may include silicone treated fumed silica particles.

The silicone treated fumed silica particles may include silicone coated fumed silica particles.

The fumed silica particles may include silicone treated fumed alumina or titania particles.

The silicone treated fumed alumina or titania particles may include silicone coated fumed alumina or titania particles.

A light emitting structure includes an optical element configured to emit light upon energization thereof, and a phosphor layer including a thixotropic agent on the optical element. The phosphor layer conforms to a shape of the optical element and has a thickness on each surface of the optical element on which the phosphor layer is formed of less than about 1000 microns. In some embodiments, the phosphor layer has a thickness of less than about 500 microns, and in further embodiments less than 100 microns.

The light emitting structure may further include a first layer including binder material and having a thickness less than about 1000 microns, wherein the first layer is directly on the LED. The first layer may be between the optical element and the conformal phosphor layer.

The phosphor particles may include first phosphor particles configured to emit light at a first dominant wavelength, and the structure may further include a second layer on the conformal phosphor layer and having a thickness less than about 1000 microns. The second layer including second phosphor particles may be configured to emit light at a second dominant wavelength.

The first dominant wavelength may be the same as the second dominant wavelength. In some embodiments, the first dominant wavelength may be different from the second dominant wavelength.

The optical element may include a wafer having a plurality of light emitting diode structures formed thereon.

The optical element may include a light emitting diode chip.

### BRIEF DESCRIPTION OF THE DRAWINGS

The accompanying drawings, which are included to provide a further understanding of the invention and are incorporated in and constitute a part of this application, illustrate certain embodiment(s) of the invention.

FIG. 1 is a flowchart illustrating operations for applying a thin layer of optical materials on a LED structure, according to some embodiments of the present invention.

FIGS. 2A-2L illustrate the application of optical materials to a mounted LED chip according to some embodiments.

FIGS. 3A and 3B illustrate the application of optical materials to different respective LED chips according to some embodiments.

FIG. 4 is a flowchart illustrating operations according to some embodiments of the invention.

FIG. 5 is a schematic diagram illustrating a pressurized deposition system for coating an optical element and/or substrate with optical materials, according to some embodiments of the invention.

FIG. 6 illustrates a spray nozzle according to embodiments of the invention.

FIG. 7 is a schematic diagram illustrating a batch deposition system for coating a light emitting diode (LED) structure with optical materials, according to some embodiments of the invention.

FIGS. 8A, 8B and 8C illustrate the application of optical materials to an LED wafer according to some embodiments.

FIG. 9 illustrates a spray deposition system.

### DETAILED DESCRIPTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Some embodiments of the present invention relate to application of an optical material to an optical element by a spray application process. Optical materials may include wavelength converting materials, luminescent materials, scattering particles, and light filters, among others. Particles as discussed herein may include small and/or large diameter particles. For example, some embodiments provide that small particles can have a mean diameter size of about 5 microns or less and can include nanoparticles. Large diameter particles can include particles having a mean diameter size of about 15 microns or greater, such as, for example, 17 microns or greater. Different types of phosphor particles may have different average particle sizes. For example, green phosphor particles made of LuAG typically have a larger average particle size than red phosphors made of CaAlSiN.

The optical materials may be provided in a luminescent suspension including a binder material, such as silicone, and a volatile solvent, such as alcohol, which decreases the viscosity of the suspension, allowing it to be atomized and sprayed onto an optical element.

In some embodiments, a thixotropic agent is added to the luminescent suspension. The thixotropic agent may include, for example, fumed silica, also known as pyrogenic silica. Fumed silica includes microscopic primary particles of amorphous silica fused into chainlike three-dimensional secondary particles which then agglomerate into tertiary particles. The resulting powder has an extremely low bulk density and high surface area. Its three-dimensional structure results in viscosity-increasing, thixotropic behavior when used as a thickener or reinforcing filler. Fumed silica has a very strong thickening effect. The primary particle size of fumed silica is about 5 nm to 50 nm. The tertiary particles are non-porous and have a surface area of 50-600 m²/g, with a density 2.2 g/cm³.

Fumed silica may be made from flame pyrolysis of silicon tetrachloride or from quartz sand vaporized in a 3000° C. electric arc. Fumed silica may be obtained from Evonik (who sells it under the name Aerosil®), Cabot Corporation (Cab-O-Sil®), Wacker Chemie (HDK®), Dow Corning, and OCI (Konasil®).

Many different materials can be used to form the thixotropic agents according to various embodiments of the present invention, with one embodiment comprising a composite material or mixture two or more oxides or ceramics. In one embodiment, the thixotropic agent can include an aluminosilicate combination of silica (SiO₂) which has an index of refraction of n≈1.46 and alumina (Al₂O₃) having an index of refraction of n≈1.7. By combining these materials in the appropriate percentage, the resulting composite thixotropic agent can have an index of refraction the same or close to that of the encapsulant, or n≈1.51 for silicone. It is understood that the other composite material can also be used such as titania-silicate composites, or fumed aluminum oxide or titanium oxide composites. For LED packages having higher index of refraction encapsulants, the concentrations of materials in the composites can be varied to allow for the refractive index of thixotropic agent to match the encapsulant. For example, in the thixotropic agent embodiment utilizing silica and alumina, greater concentrations of alumina can be used to increase the refractive index, or reduced amounts can be used to reduce the refractive index.

Although the composite thixotropic agents are described above combining two materials, it is understood that they can comprise composites of many more than two materials. In these embodiments one or more of the materials can have a refractive index lower than the encapsulant's, and one or more can have a refractive index higher that the encapsulant's. The materials can be combined in different concentrations to achieve the desired refractive index. In the following description, fumed silica is used as the thixotropic agent. However, it will be appreciated that other types of thixotropic agents having the properties described herein can be used in a spray application.

To allow for the desired rheology or thickness control, the resulting composite thixotropic agent should also include particles having a large surface area and/or small particle size. In some embodiments, the particles can comprise a surface area of between about 100 m²/g and 200 m²/g, and in further embodiments between about 100 m²/g and 150 m²/g.

Adding a thixotropic agent to a suspension including a viscosity reducing solvent would superficially appear to be counterproductive, as it would be expected to cause clogging of a spray nozzle used to spray the luminescent suspension onto an optical element. However, the present inventors have discovered that adding fumed silica to a luminescent suspension including relatively heavy particles, such as phosphor particles, scattering particles, etc., can decrease or delay the “settling” of the added particles while still allowing the luminescent suspension to flow easily through a spray nozzle.

One problem commonly encountered with spray deposition of phosphor particles is that phosphor particles in the luminescent suspension can settle, or fall out of suspension, especially in a reservoir from which the suspension is drawn just prior to spray deposition. This settling of particles can result in uneven distribution of phosphor particles in the spray pattern. The problem can be even greater in luminescent suspensions including different types of phosphor particles, which may have different settling rates. For example, as noted above, green phosphor particles may have a larger average particle size than red phosphor particles. Consequently, green phosphor particles may settle at a faster rate than red phosphor particles. The result is that the composition of the spray may change over time as the luminescent suspension in the reservoir is depleted, causing different optical elements sprayed with the luminescent suspension to have different optical properties, such as different color points.

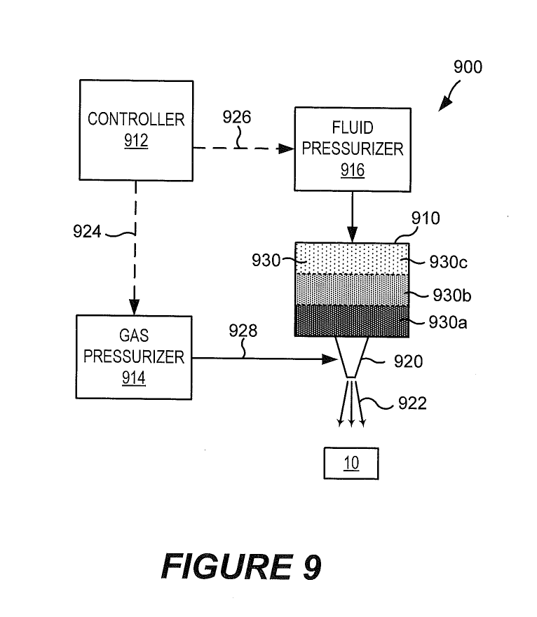

For example, FIG. 9 illustrates a spray deposition system 900 for spraying a luminescent suspension 930 contained in a reservoir 910 onto an optical element 10. The spray deposition system includes a fluid pressurizer 916 that pressurizes the fluid contained in the reservoir 910 and a gas pressurizer 914 that supplies pressurized gas to a spray nozzle 920 coupled to the reservoir 910. The fluid pressurizer 916 and the gas pressurizer 914 are controlled by control signals 926, 924 generated by a controller 912.

In the example shown in FIG. 9, the luminescent suspension 930 includes three types of phosphor particles, namely, red, yellow and green phosphor particles. Of the three types of phosphors, the green phosphor particles have the largest average particle size, and the red phosphor particles have the smallest particle size. Because the phosphors have different average particle sizes, they may settle, or fall out of suspension, at different rates. Thus, after some amount of time, the luminescent suspension may self-organize into distinct layers 930a, 930b, 930c, where layer 930a (the lowest layer) has a predominant concentration of green phosphor particles, layer 930b (the middle layer) has a predominant concentration of yellow phosphor particles, and 930c (the highest layer) has a predominant concentration of red phosphor particles. Thus, as the luminescent suspension is sprayed out onto a plurality of optical elements, the first optical elements sprayed may have too much green phosphor, while later-sprayed optical elements may have too much yellow or red phosphor. This is an undesirable result, as it reduces product uniformity, lowers yield, and increases production costs.

Moreover, the changing composition of the luminescent suspension also changes the viscosity of the luminescent suspension. Thus, for example, the flow rate of the luminescent suspension through the spray nozzle may be slower at first and then increase as the viscosity of the suspension changes as the more dense material is consumed and the less dense material remains. This may result in “wetter” topcoats of luminescent material which can change the shape of the sprayed material and encourage slumping.

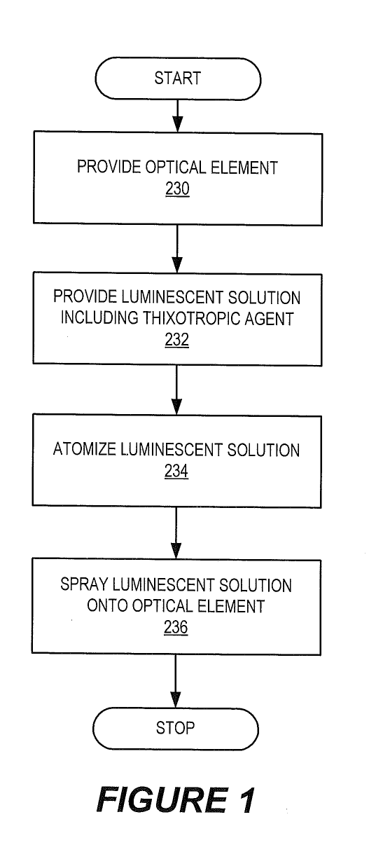

Reference is now made to FIG. 1, which is a flow diagram illustrating operations for applying a thin layer of optical materials on an optical element, according to some embodiments of the present invention. In some embodiments, the thin layer may be a layer having a thickness of less than 1000 microns, in some cases less than 500 microns, and in some cases less than 100 microns. The thin layer may in some cases be a conformal layer. In general, a conformal layer is a layer that conforms to the shape of the optical element on which it is applied, and that has a thickness that is similar on each surface of the optical element on which the conformal layer is applied.

The optical element may include an LED structure such as, for example, an LED chip, device and/or wafer of multiple LED chips, among others. In some embodiments, the optical element or device may include a light transmissive, reflective, and/or support structure, among others. For example, the optical element or device may include planar, non-planar, two-dimensional, three-dimensional, lenses, reflectors, emitter packages, primary and/or secondary optics, among others. Some embodiments provide that the optical element or device may include a transparent carrier on which optical materials are applied such as, for example, phosphor material to provide a luminescent effect that is remote from the light emitting structure.

In a first operation illustrated in FIG. 1, an optical element, such as a light emitting diode (LED) chip, a plurality of LED chips on a carrier, an LED wafer, etc., is provided (block 230).

A luminescent suspension including an optical material that is suspended in solution is also provided (block 232). The luminescent suspension includes a thixotropic agent, such as fumed silica, fumed alumina, etc., therein. In some embodiments, the thixotropic agent includes a hydrophobic silica, such as silicone-treated fumed silica. One example of a hydrophobic silica is CAB-O-SIL® TS-720 manufactured by Cabot Corporation, which is a medium surface area fumed silica that has been surface treated with polydimethylsiloxane PDMS, resulting in a hydrophobic silica. This material has a minimum surface area per unit mass specification of 105.0 m²/g, an average surface area per unit mass of 120.1 m²/g, and a maximum surface area per unit mass of 135.0 m²/g. Using silicone-treated fumed silica may reduce the agglomeration of the fumed silica in the luminescent solution, which may reduce clogging of a spray nozzle notwithstanding the addition of fumed silica as a thixotropic agent. Hydrophobic silica or alumina, such as silicone treated fumed alumina or titania may also be used.

While not wishing to be bound by a particular theory, it is presently believed that silicone treatment of the fumed silica causes the fumed silica to preferentially mix with the binder material rather than agglomerating with itself. This is believed to allow the luminescent solution to flow smoothly while preserving the ability of the fumed silica to reduce or prevent the phosphor particles in the luminescent suspension from falling out of suspension. Because the fumed silica tends to keep the phosphor particles from falling out of suspension, the luminescent solution may maintain a more homogeneous composition during the spray deposition process, resulting in more a consistent composition of the deposited phosphor particles.

That is, the present inventors have observed that silicone treated fumed silica appears to retard or limit the settling of particles in the luminescent suspension, but does not substantially adversely affect the flow viscosity of the luminescent suspension.

In some embodiments, the amount of fumed silica added to the luminescent suspension may be less than about 1.0% by weight. In some embodiments, the amount of fumed silica added to the luminescent suspension may be less than about 0.8% by weight. In some embodiments, the amount of fumed silica added to the luminescent suspension may be between about 0.5% and about 1.0% by weight, and in some embodiments about 0.75% by weight. The amount of fumed silica present in the luminescent suspension may affect the optical characteristics of the resulting device, because too much fumed silica may cause undesirable internal scattering and/or reflection, which can reduce the amount of light usefully extracted from the optical element. Thus, it may in some embodiments be desirable to keep the amount of fumed silica in the luminescent suspension relatively low. Keeping the amount of fumed silica in the luminescent suspension relatively low may also reduce the possibility that the fumed silica will agglomerate before the luminescent suspension is sprayed onto an optical element.

In some embodiments, the fumed silica particles may have a ratio of surface area per unit mass greater than about 100 m²/g. In some embodiments, the fumed silica particles may have a ratio of surface area per unit mass between about 100 m²/g and about 200 m²/g, and in some cases between about 100 m²/g and about 150 m²/g.

In some embodiments, the fumed silica particles may have an average particle length of between about 300 microns and about 400 microns.

The amount of fumed silica present, and the ratio of surface area per unit mass and the average particle length of the fumed silica particles, may affect the amount by which the fumed silica agglomerates. If the surface area per unit mass of the fumed silica is too low, the fumed silica particles may not be able to effectively reduce settling of phosphor particles, while if the surface area per unit mass of the fumed silica is too high, the fumed silica particles may undesirably clog a spray nozzle used to spray the luminescent suspension. That is, if the fumed silica agglomerates too little, it may not be sufficiently thixotropic to keep the phosphor particles from falling out of suspension, and if the fumed silica agglomerates too much, it may cause the spray nozzle to clog.

The luminescent suspension is then atomized using a flow of pressurized gas (block 234). The atomized luminescent suspension is then sprayed onto the LED structure using the flow of pressurized gas (block 236). For example, the optical material may be sprayed using an air pressurized spray system.

The optical material may include wavelength conversion particles suspended in a solution including a volatile solvent and a binder material. Some embodiments provide that the volatile liquid is evaporated via thermal energy in the heated optical element. In this manner a thin conformal layer of material including wavelength conversion particles may be provided on the optical element. Some embodiments provide that the solution includes a nonvolatile liquid. In such embodiments, the nonvolatile liquid may be cured via the thermal energy in the heated optical element.

The optical element may include an LED chip having a top surface with a wirebond pad on the top surface. A wire may be bonded to the wirebond pad before heating the LED chip and before spraying the luminescent suspension onto the LED chip. Some embodiments provide that the optical element includes an LED wafer and that the wafer is singulated into multiple LED chips after providing the conformal layer.

In some embodiments, the optical element may be heated by a heating device prior to application of the luminescent suspension. The heating device may include electrical resistive and/or inductive heating components and/or combustion related heating components. Some embodiments provide that the optical element is heated and then subsequently processed after a heating operation. The heating device may be configured to provide heat throughout the subsequently described operations. In some embodiments, a first heating device may provide an initial heating of the optical element and then a second heating device may provide a maintenance heating operation. In some embodiments, the optical element may be heated to a temperature in a range of about 90 degrees Celsius to about 155 degrees Celsius.

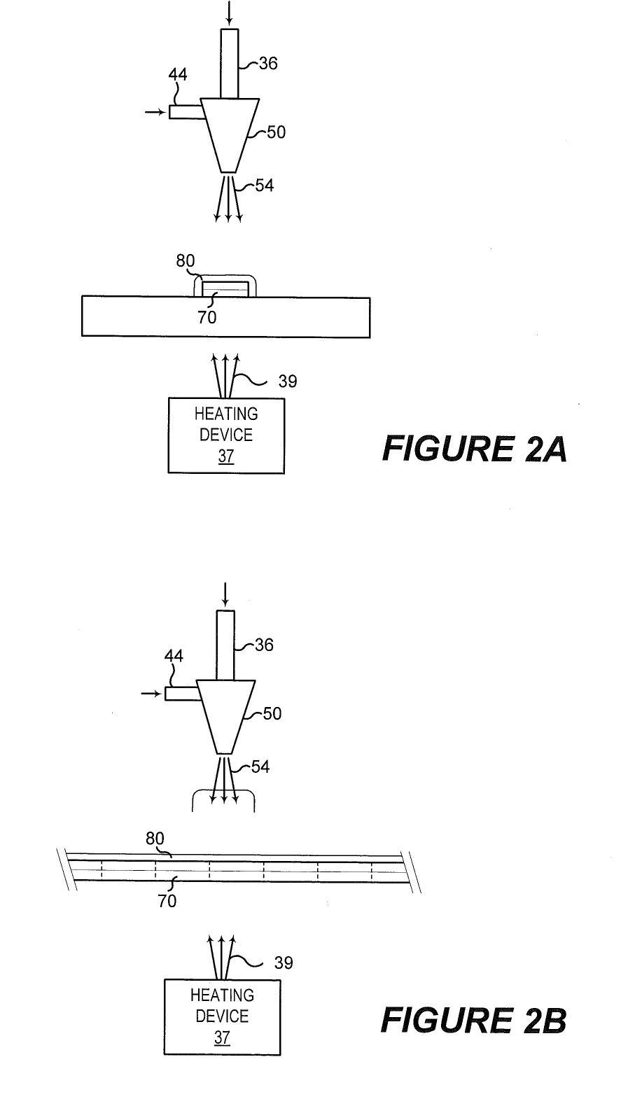

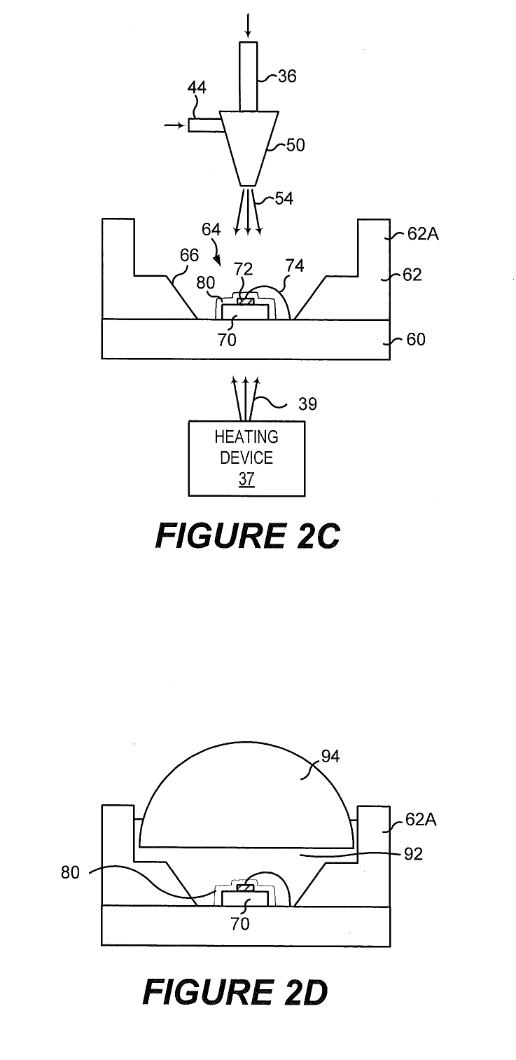

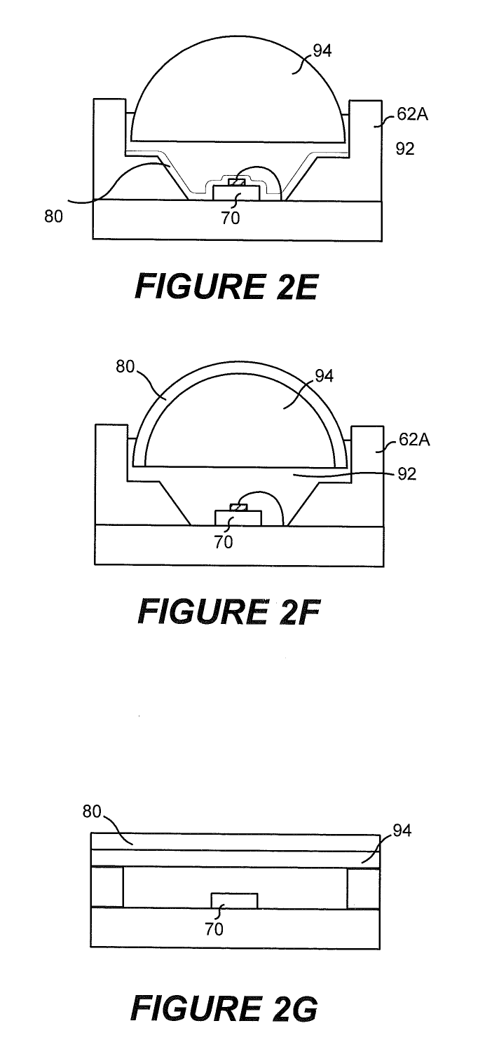

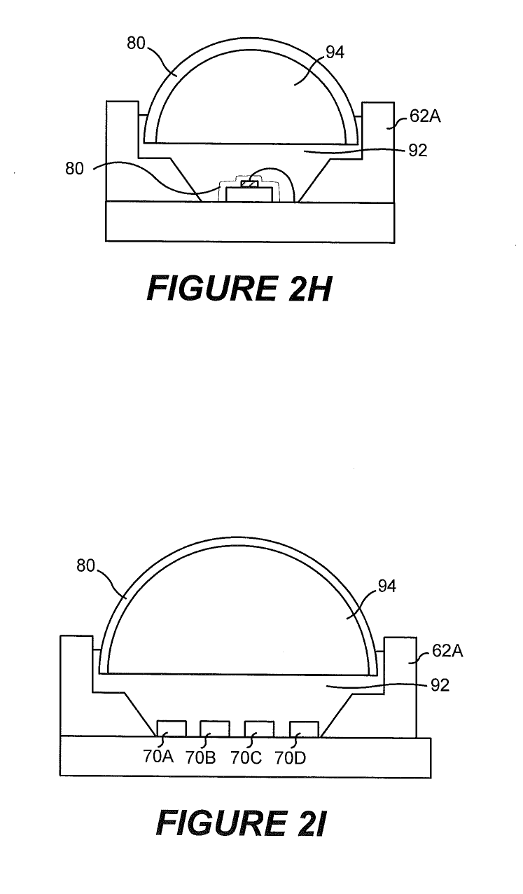

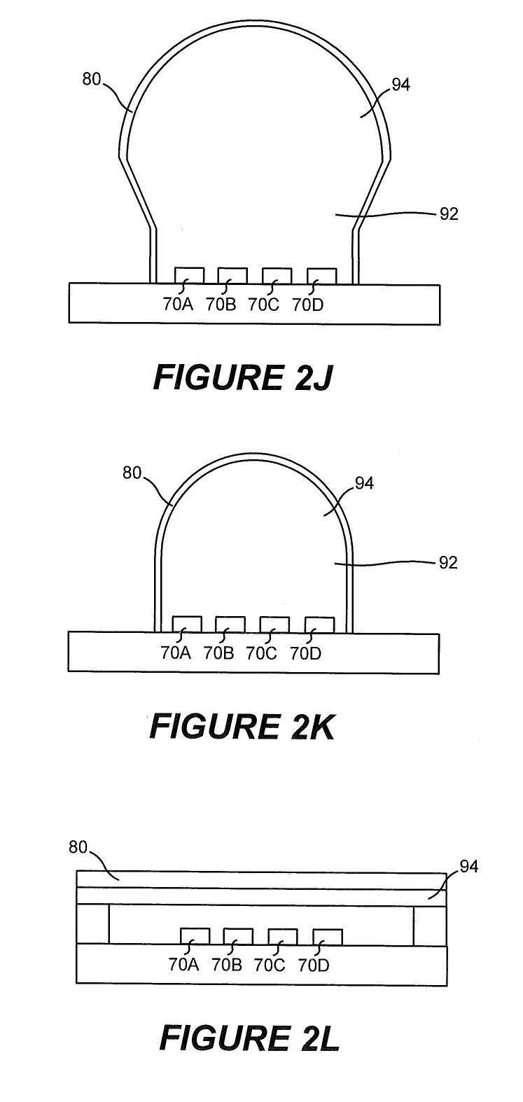

In spraying large areas, such as, for example, an LED wafer, the speed and height of the nozzle 50 (FIG. 2A) may be adjusted to achieve uniform coverage over such areas. Some embodiments provide that an acceleration of the nozzle 50 (FIG. 2A) may be used prior to the application of the optical materials to provide uniformity of the conformal layer. In some embodiments, the optical materials may be applied to multiple LED wafers in the same operation(s) to further improve uniformity and to reduce waste of the optical materials during the acceleration portion. Additionally, by varying process temperatures, a flow time after application may be controlled to achieve desired coverage.

Another problem that is encountered during spraying of an optical coating consisting of silicone and phosphor particles is the ability to maintain a truly conformal coat. Angled surfaces such as found on SiC-based blue LEDs for light extraction and vertical surfaces such as found on sapphire-based blue LEDs and corners found on shapes with flat surfaces tend to fight a true conformal coat. If the surface is heated or as the silicone is cured, the silicone may experience a precipitous drop in viscosity, which causes particles to flow and gravity to sag/flow the silicone and avoid high stress areas of the optical element structure, such as corners. The addition of fumed silica specifically retards and combats this sagging due to its thixotropic nature. The improved nature of the conformal coating is evidenced by improved farfield uniformity for devices including conformal phosphor coatings formed with fumed silica.

In some embodiments, multiple conformal layers of optical materials having the same and/or different optical materials may be applied. Since each conformal layer may rapidly cure once it is deposited on the heated LED structure, subsequent layers may be applied directly thereafter. However, some embodiments provide that the LED structure may be allowed to cool between layers and then heated again for subsequently applied conformal layers.

The atomized luminescent suspension may be applied at different and/or multiple angles, directions and/or orientations to affect uniformity of the conformal layer.

Referring now to FIGS. 2A-2L, application of optical materials to LED structures is illustrated. In the embodiments of FIGS. 2A-2L, the optical materials 54 including fumed silica are applied to an LED chip or die 70 mounted on a substrate 60. However, as explained above, optical materials 54 may be applied in a similar manner to bare (i.e. unmounted) LED die and/or to LED wafers. Accordingly, in some embodiments, optical materials 54 may be applied to the lens 94 and/or the reflector cup 62. An LED wafer includes a wafer substrate on which thin epitaxial layers forming an LED active layer have been formed and/or mounted. Accordingly, an LED wafer can include a growth substrate on which the epitaxial layers have been grown and/or a carrier substrate to which the epitaxial layers have been transferred.

Referring to FIG. 2A, heating device 37 may provide heat to an LED chip 70. Some embodiments provide that a nozzle 50 is configured to spray the optical materials 54 onto the heated LED chip 70 to provide conformal layer 80. As can be seen in FIG. 2A, the LED chip 70 has an upper surface and opposing side surfaces on which the conformal layer is formed. The conformal layer 80 has a thickness that is about the same on each of the surfaces of the LED chip 70 on which it is formed.

Similarly, referring to FIG. 2B, a wafer of LED chips 70 may be heated and the optical materials 54 may be applied thereon to provide a conformal layer 80. The LED chips 70 may be singulated after the optical materials are applied.

As shown in FIG. 2C, an LED chip 70 is mounted on a substrate 60. The LED chip 70 can be mounted on the substrate 60 through an intermediary structure, such as a bonding pad and/or submount (not shown). In some embodiments, the LED chip 70 can be mounted in an optical cavity 64 defined by a reflector cup 62 that is placed on the substrate 60. The reflector cup 62 includes an angled reflective surface 66 facing the LED chip 70 and configured to reflect light emitted by the LED chip 70 away from the optical cavity 64. The reflector cup 62 further includes upwardly extending sidewalls 62A that define a channel for receiving and holding a lens 94 (FIG. 2D).

It will be appreciated that the reflector cup 62 is optional. For example, the LED chip 70 could be mounted on a substrate 60, printed circuit board or other support member without any reflector around the LED chip 70. Moreover, the reflector cup 62 and the substrate 60 could be merged together as a unitary structure. The substrate 60 could also include a leadframe, and a package body may be formed on the leadframe surrounding the LED chip 70 and defining the optical cavity 64. Accordingly, the LED chip 70 could be mounted in many different styles of packaging, and the present invention is not limited to the particular packaging configuration shown in the figures.

Still referring to FIG. 2C, the LED chip 70 can include a wirebond pad 72, and a wirebond connection 74 can be formed from the wirebond pad 72 to a corresponding contact pad (not shown) on the substrate 60 or elsewhere. However, it will be appreciated that the LED chip 70 could be a horizontal LED chip having both anode and cathode contacts on the same side of the chip, and could be mounted in flip-chip fashion on the substrate 60, so that no bond wire connections may be made to the LED chip in some embodiments.

Referring to FIGS. 5, 6 and 2C, the controller 20 of the pressurized deposition system 100 can cause the liquid in the supply line 36 to be supplied to the spray nozzle 50. For example, the controller 20 can open the MFCs 34A, 34B and 34C and the valve 40 and close the MFC 34D. A desired concentration of optical materials 54, such as phosphor particles and/or diffuser particles can be provided into the supply line 36 by controlling the MFCs 34C, 34D. Any remaining materials in the supply line 36 left from prior applications of materials can be purged prior to deposition of the solvent, binder and phosphor material.

In some embodiments, the phosphor particles may include commercially available YAG:Ce, although a full range of broad yellow spectral emission is possible using conversion particles made of phosphors based on the (Gd,Y)₃(Al,Ga)₅O₁₂:Ce system, such as the Y₃Al₅O₁₂:Ce (YAG). Other yellow phosphors that can be used for white emitting LED chips include:

Tb₃₋ₓREₓO₁₂:Ce(TAG); RE=Y, Gd, La, Lu; or Sr_{2-x-y}BaₓCa_{y}SiO₄:Eu.

In other embodiments, the LED chip can include blue emitting LED coated by other phosphors that absorb blue light and emit yellow or green light. Some of the phosphors that can be used for these LED chips include:

Yellow/Green

(Sr,Ca,Ba)(Al,Ga)₂S₄:Eu²⁺

Ba₂(Mg,Zn)Si₂O₇:Eu²⁺

Gd_{0.46}Sr_{0.31}Al_{1.23}OₓF_{1.38}:EU²⁺_{0.06}

(Ba_{1-x-y}SrₓCa_{y}) SiO₄:Eu

Ba₂SiO₄:Eu²⁺

The packages can also include a phosphor that absorbs the LED light and emits a red light. Some phosphors appropriate for this structures can include:

Red

Lu₂O₃:Eu³⁺

(Sr₂₋ₓLaₓ)(Ce₁₋ₓEuₓ)O₄ Sr₂Ce₁₋ₓEuₓO₄ Sr₂₋ₓEuₓCeO₄

SrTiO₃:Pr³⁺,Ga³⁺

CaAlSiN₃:Eu²⁺

Sr₂Si₅N₈:Eu²⁺

Still other packages may include a phosphor that absorbs the LED light and emits a green light. Some phosphors appropriate for this structures can include:

Green

LuAG:Ce (Lanthanide+YAG)

BOSE (Ba, O, Sr, Si, Eu)

Still other packages can include mixtures of yellow, yellow-green, green and/or red phosphors.

Each of the phosphors described above exhibits excitation in the desired emission spectrum, provides a desirable peak emission, has efficient light conversion, and has acceptable Stokes shift. It is understood, however, that many other phosphors can used in combination with other LED colors to achieve the desired color of light.

The heating device 37 may apply heat 39 to increase the temperature of the LED chip 70, the substrate 60, the reflector cup 62 and the wirebond pad 72. The liquid in the supply line 36 is sprayed onto the LED chip 70, forming a thin layer of the atomized binder, solvent and phosphor material (conformal layer) 80 thereon. The thermal energy from the heated LED chip 70 and substrate 60 may cause the applied binder, solvent and phosphor to cure rapidly. In some embodiments, the rapid curing may be referred to as snap-curing. By snap-curing the applied binder, solvent and phosphor, a substantially uniform and conformal layer of phosphor may be provided on the LED chip 70 and the substrate 60. As noted above, the liquid binder material can include a material such as silicone and/or epoxy. Some embodiments provide that the liquid solvent may include a volatile liquid solvent, such as alcohol or other volatile material.

Via the thermal energy of the heated substrate 60 and LED chip 70, the volatile solvent liquid may then be evaporated off, leaving the optical materials (e.g., phosphor particles and/or diffuser particles) in the binder material to provide the conformal layer 80. However, in some cases, a non-volatile liquid, such as silicone and/or epoxy resin, may be used as a carrier liquid for the phosphor/diffuser particles, in which case the non-volatile liquid may be cured by the thermal energy of the heated substrate 60 and LED chip 70 to provide a conformal layer 80 of optical material over the LED chip 70. The conformal layer 80 may have a thickness that is less than about 1000 microns (and in some cases less than 500 microns or even 100 microns), and may have a substantially consistent thickness on the upper surfaces and sidewalls of the LED chip 70. In some embodiments, the conformal layer may have a thickness of about 70-80 microns, and in some embodiments the conformal layer may have a thickness of about 50 microns.

Referring to FIG. 2D, after spray-coating the LED chip 70 with the conformal layer 80 of binder and phosphor material, an encapsulant material 92, such as silicone and/or epoxy, can be dispensed to at least partially fill the optical cavity 64, and a lens 94, such as a glass or silicone lens, can be positioned over the LED chip 70. Curing the encapsulant material 92 secures the lens 94 to the structure, while the vertical wall portions 62A of the reflector cup 62 allow the lens to travel as the encapsulant material 92 expands and contracts with heating/cooling cycles.

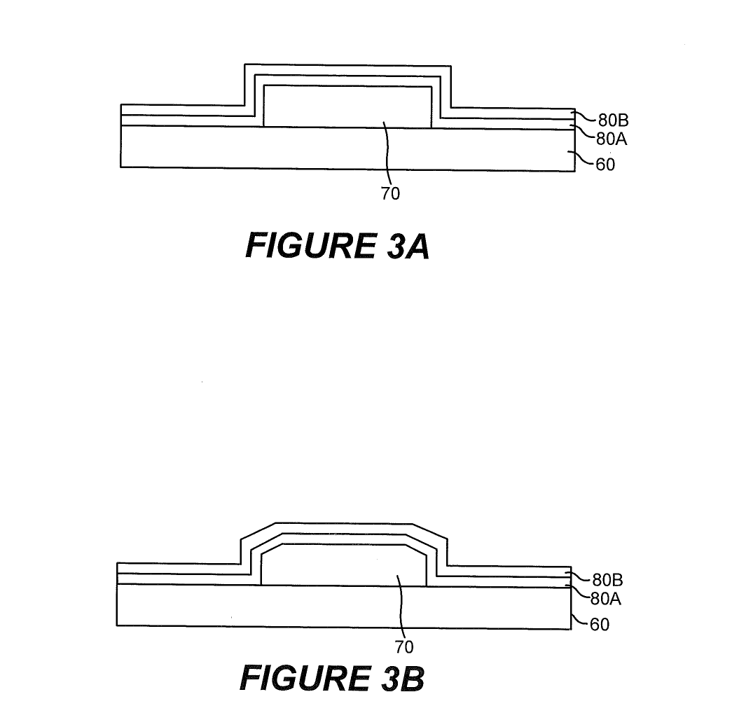

In some embodiments, spray-coating of the conformal layers 80 on the heated LED chip 70 and substrate 60 can be performed multiple times using the same and/or different optical materials. For example, referring to FIGS. 3A and 3B, a layer 80A including a first phosphor may be coated onto an LED chip 70 on a submount 60. A layer 80B of the same or of another optical material, such as phosphor particles and/or diffuser particles, can be formed on the layer 80A in the manner described above. Other layers of the same and/or of another optical materials, such as phosphor particles and/or diffuser particles, can be successively formed on the layer 80B in the manner described above. FIG. 3B further illustrates that application of the conformal layer(s) 80 may be particularly beneficial when the LED chip includes non-planar surfaces, such as, for example, bevels, among others. The thermal energy from the heated LED chip 70 and substrate 60 may cause the applied binder, solvent and phosphor to cure rapidly. In some embodiments, the rapid curing may be referred to as snap-curing. By snap-curing the applied binder, solvent and phosphor, a substantially uniform and conformal layer of phosphor may be provided on the LED chip 70 and the substrate 60.

Referring to FIG. 2E, some embodiments provide that the liquid in the supply line 36 is sprayed onto the LED chip 70 and the surrounding structure, such as, for example, the reflector cup 62 thus forming a conformal layer 80 thereon. Additionally, referring to FIG. 2F, in some embodiments, the conformal layer 80 may be formed on an exterior and/or interior surface of a lens 94, which is heated to cause the conformal layer 80 to cure when applied thereto. Reference is made to FIG. 2G, which illustrates that the conformal layer 80 may be applied to a two-dimensional structure, such as, for example, a lens 94 or other transmissive and/or reflective optical element. Brief reference is made to FIG. 2H, which illustrates that the conformal layer 80 may be applied to a heated lens 94 and the heated LED chip 70.

Reference is made to FIG. 2I, which illustrates multiple LED chips 70A-D that are electrically connected on a bottom of the LED chip. For example, the LED chips 70A-D may include flip-chips having no wire bond for electrical termination. The LED chips 70A-D may be configured to emit light at one or more different dominant wavelengths and/or combinations thereof. A conformal coating 80 may be provided on the outside and or inside of a lens 94. FIGS. 2J, 2K and 2L illustrate multiple non-wire bonded LED chips 70A-D configured inside a lens 94 that includes a conformal layer 80 as described herein. Some embodiments provide that conformal coating may be applied to one or more of the multiple LED chips 70A-D in addition to or in alternative to the lens 94. In some embodiments, the LED chips could be wirebonded.

A conformal layer 80 applied to a lens 94 may be performed after during and/or before assembly with the LED chips 70A-D. For example, some embodiments provide that an array of multiple lenses may be heated and then the optical materials applied thereto. Similarly, micro molds could be sprayed to form optical material elements that may be removed from the mold and placed over an optical element, such as an LED chip.

FIGS. 3A and 3B show an LED chip 60 mounted to a submount or substrate 60 with different layers 80A and 80B of optical materials. Additional or intervening layers are possible. The different layers 80A and 80B of optical materials can include the same or different optical materials. For example, the layers 80A and 80B of optical material can include a first and second types of phosphor particles. In some embodiments, phosphor particles having different sizes can be in the different layers. Some embodiments provide that additional layers of optical material can include other phosphor particles and/or diffuser particles, among others.

In some embodiments, the layer 80A of optical material can include phosphor particles configured to convert incident light to a first wavelength (e.g. yellow), while the layer 80B of optical material can include phosphor particles configured to convert incident light to a second wavelength, different from the first wavelength (e.g. red). Accordingly, light output by the packaged LED chip 70 can be a mixture of primary light emitted by the LED chip 70 and secondary light emitted by the layer 80A of phosphor and the layer 80B of phosphor. Such light can have improved color rendering properties compared to light generated using only one kind of phosphor.

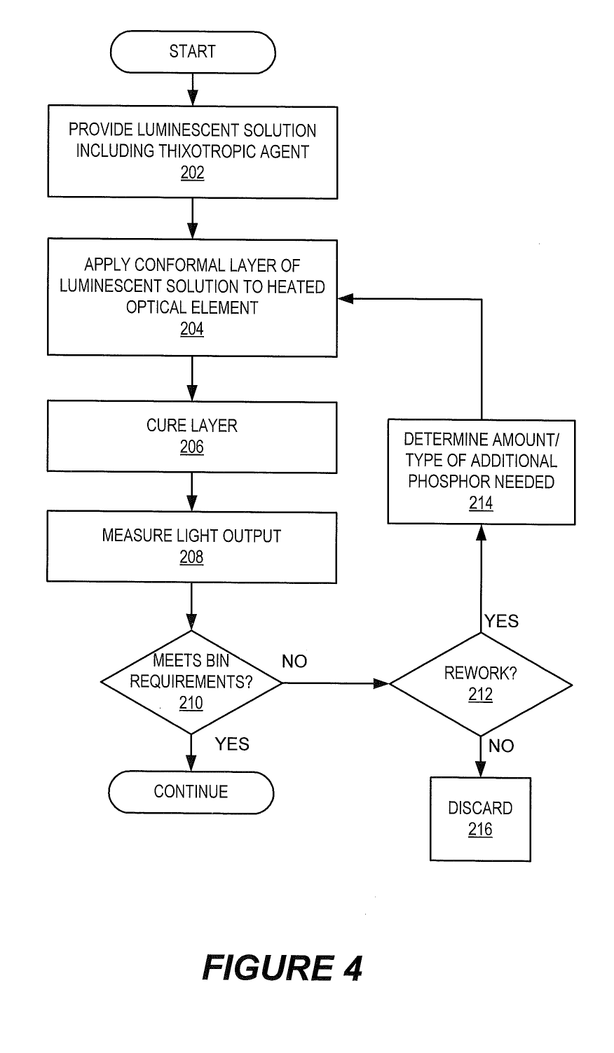

In some embodiments, the layer 80A of optical material and the layer 80B of optical material can include the same type of phosphor. For example, referring to FIGS. 3, 4 and 5, an optical element, for example, an LED structure, such as an LED chip 70, may be heated (block 202). Some embodiments provide that the optical element may include substrates and/or optical devices. A conformal layer 80A of optical material may be applied to a heated optical element using a spray deposition system 100 according to embodiments of the invention (block 204). The solvent can then be rapidly evaporated and/or cured, depending on whether the solvent is volatile or non-volatile, by virtue of the thermal energy in the heated optical element so that the binder material can be cured to adhere the optical materials (e.g., phosphor particles, etc.) to the optical element (e.g., LED chip 70, etc.) (block 206). Some embodiments provide that the optical element could then be stored, e.g. at room temperature, to be later retrieved for further tuning.

The optical element can then be energized, for example, by applying a voltage across anode and cathode terminals of an emitting portion, and the optical characteristics (e.g., power output, color point, CCT) of the device including the conformal layer 80A can be measured. In particular, the output power (brightness), color point and/or correlated color temperature (CCT) of the LED structure can be measured (block 208). For example, the light output by the LED structure can be measured by an optical sensor 35, and the results can be provided to the controller 20. Testing the optical element may be easiest as an LED structure including a mounted LED chip. When an LED structure includes an LED wafer, it may be possible to test representative areas/devices on the wafer instead of testing every device on the wafer, and tune the entire wafer based on the light output from the test locations.

A test is then performed to determine if the optical characteristics of the wafer are acceptable, i.e. to see if the wafer meets established binning requirements (block 210). If the optical characteristics of the structure are unacceptable, a decision is made at block 212 whether to discard the device (block 216) or rework the device. However, if the optical characteristics are satisfactory, the manufacturing process proceeds to the next manufacturing step.

If it is determined that the device can be reworked, the light output corresponding to the optical element can be tuned by determining the amount and type of additional phosphor needed to correct the color point/CCT of the structure (block 214). A second conformal layer 80B can be applied (block 202). In some embodiments, the test may be performed while the optical element is still heated. Some embodiments provide that the optical element is reheated for applying the second conformal layer 80B. The second conformal layer 80B may include the same and/or different type from the phosphor used in the first conformal layer 80A and can be applied using the spray deposition system 100 under the direction of the controller 20.

In general, the operations of blocks 202-214 can be repeated as desired to achieve the desired optical characteristics, as illustrated in conformal layers 80C and 80D. However, if too much phosphor is applied, the light emission characteristics may deteriorate due to reabsorption and/or excessive absorption of light from the optical element, at which point the optical element may fail the test at block 210.

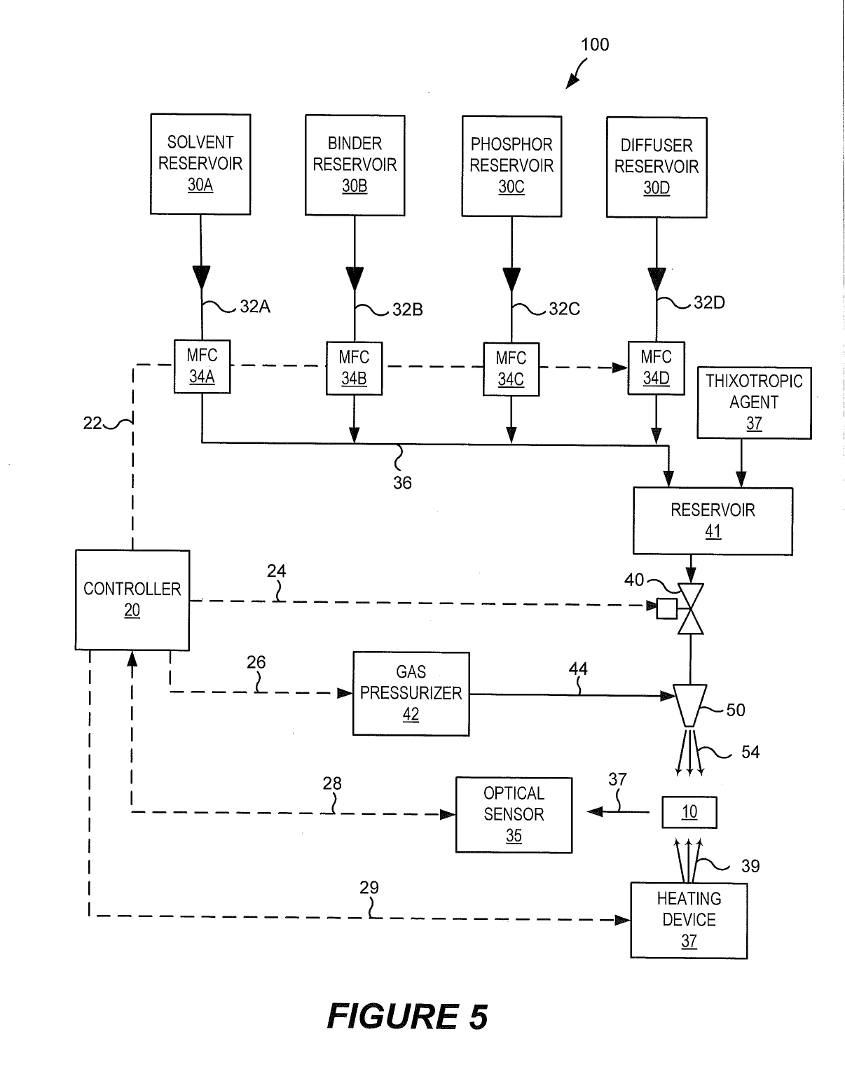

FIG. 5 is a schematic diagram illustrating a pressurized deposition system 100 for coating an optical element 10 with optical materials 54, such as luminescent particles and/or diffuser particles. In some embodiments, the optical element 10 may include a light emitting structure, such as, for example, a light emitting diode (LED), whereas some embodiments provide that the optical element 10 includes a light transmissive, reflective, and/or support structure, among others. For example, the optical element 10 may include planar, non-planar, two-dimensional, three-dimensional, lenses, reflectors, emitter packages, primary and/or secondary optics, among others. Some embodiments provide that the optical element 10 may include a transparent carrier on which optical materials 54 are applied such as, for example, phosphor material to provide a luminescent effect that is remote from the light emitting structure.

According to some embodiments, the optical materials 54 are sprayed onto the optical element 10 by the system 100. Some embodiments provide that the optical materials 54 are applied using application techniques such as pouring, dipping, rolling, brushing and/or stamping, among others. A heating device 37 applies heat (thermal energy) 39 to the optical element 10 to increase the temperature of the optical element 10 prior to spraying the optical materials 54 thereon. As shown in FIG. 1, a supply line 36 supplies a carrier liquid containing the optical materials 54 to a spray nozzle 50. The carrier liquid is sprayed onto an optical element 10 via the spray nozzle 50. In particular, pressurized gas supplied to the spray nozzle 50 through a high pressure gas supply line 44 atomizes the carrier liquid and directs the optical materials 54 towards the optical element 10 where the optical materials 54 are deposited, as described in more detail below. Some embodiments provide that the optical materials 54 are an atomized liquid. The term “atomize” is used herein in a general sense to refer to reducing a liquid to minute particles and/or to a fine spray. A conformal layer including the optical materials 54 may be provided from a rapid curing of the atomized liquid when deposited on the heated optical element 10. For example, the curing time of optical materials 54 applied to a heated optical element 10 may be substantially shorter than that of optical materials 54 applied to a non-heated optical element. In this manner, settling, separation and/or stratification of the optical materials 54 may be significantly reduced or eliminated. Accordingly, better layer bonding and more uniformity in layer thickness and composition may be achieved.

The optical element 10 can include an LED wafer, a mounted LED die and/or an unmounted (i.e. bare) LED die. In some embodiments, the LED structure may include a light transmission and/or reflection element that is configured to transmit and/or reflect light received from an emitter. In such embodiments, the light transmission and/or reflection element may be configured to be heated and then have the optical materials 54 deposited thereon. The light transmission and/or reflection elements may be planar (2-dimensional) and/or 3-dimensional. Some embodiments provide that in order to receive light, the light transmission and/or reflection element may be in contact with, proximate to, and/or spaced apart from the LED die. Accordingly, systems and methods according to embodiments of the invention can be used at various stages of a manufacturing process.

In some embodiments, the liquid in the supply line 36 may include a binder that includes organic and/or organic-inorganic hybrid materials. Some embodiments provide that the liquid in the supply line 36 can include, for example, a binder material, such as liquid silicone and/or liquid epoxy, and/or a volatile or nonvolatile solvent material, such as alcohol, water, acetone, methanol, ethanol, ketone, isopropynol, hydrocarbon solvents, hexane, ethylene glycol, methyl ethyl ketone, xylene, toluene, and combinations thereof. In some embodiments, the binder may have an index of refraction of greater than about 1.25. Some embodiments provide that that the index of refraction of a binder material may be greater than about 1.5. It may be desirable to have high light transmission across the visible spectrum. In some embodiments, the binder may have a transmission of light including about 90% or greater in a wavelength range including about 440 nm to about 470 nm at thicknesses as described herein. In some embodiments, the binder may have a transmission of light including about 95% or greater in a wavelength range including about 440 nm to about 470 nm at thicknesses as described herein. In some embodiments, the binder may have a transmission of light including about 98% or greater in a wavelength range including about 440 nm to about 470 nm at thicknesses as described herein. In some embodiments, the binder may have a transmission of light including about 90% or greater, about 95% or greater, and/or about 98% or greater for other wavelengths in the visible spectrum, such as green, yellow and/or red. In general, a volatile solvent dries or evaporates off shortly after being deposited. A volatile or nonvolatile solvent material can include particles therein that are to be deposited onto the LED structure, such as particles of a luminescent material (e.g. a phosphor) and/or particles of a light-scattering material, such as titanium dioxide, among others. The liquid in the supply line 36 is provided from one of a plurality of fluid reservoirs 30A to 30D, which are attached to the supply line 36 through respective input lines 32A to 32D. The flow of liquid through the input lines 32A to 32D can be carefully controlled by electronically-controlled mass flow controllers 34A to 34D, respectively,

As shown in FIG. 5, the reservoirs 30A to 30D can include a solvent reservoir 30A that contains a volatile liquid solvent, such as alcohol, water, etc., and a binder reservoir 30B that contains a liquid binder material, such as liquid silicone and/or liquid epoxy. In some embodiments, the solvent reservoir 30A and the binder reservoir 30B can include “pure” liquids, that is, liquids that do not contain any phosphor, diffuser, or other particles therein. The reservoirs 30A to 30D can also include a phosphor reservoir 30C that contains a liquid solvent in which a concentration of phosphor particles is suspended. In some embodiments, the phosphor reservoir 30C can include phosphor particles at a concentration that is greater than a concentration at which the phosphor particles will be applied onto the optical element 10.

The reservoirs 30A to 30D can also include a diffuser reservoir 30D that contains a liquid solvent in which a concentration of diffuser particles is suspended. In some embodiments, the diffuser reservoir 30D can include diffuser particles at a concentration that is greater than a concentration at which the diffuser particles will be applied onto the optical element 10.

One or more of the reservoirs 30A to 30D can be pressurized, so that flow from the reservoirs 30A to 30D can be obtained by positive pressure into the supply line 36. In particular, the solvent reservoir 30A and the binder reservoir 30B can be pressurized. In some embodiments, the phosphor reservoir 30C and/or the diffuser reservoir 30D may not be pressurized, so that flow from the phosphor reservoir 30C and/or the diffuser reservoir 30D may be induced into the supply line 36 by negative pressure caused by flow through the supply line 36. The pressure in the liquid supply line 36 need not be high, since the force for spraying the liquid onto the optical element 10 is provided by a high-pressure gas line 44.

The flow of liquid through the supply line 36 can be controlled by an electronically controllable valve 40. When the valve 40 is open, liquid in the supply line 36 is supplied to the spray nozzle 50.

FIG. 6 illustrates a spray nozzle 50 according to embodiments of the invention in greater detail. Referring to FIGS. 5 and 6, pressurized gas (e.g., pressurized air) generated by a gas pressurizer 42 may be supplied to the spray nozzle 50 through the pressurized gas supply line 44. The pressurized gas is directed to through a gas outlet port 52 in the spray nozzle 50 that is adjacent a liquid outlet port 51. The flow of liquid through the liquid outlet port 51 can be regulated, for example, by controlling the position of a retractable pin 53. When the pin 53 is retracted, the liquid outlet port 51 is opened. The flow of pressurized gas out of the gas outlet port 52 creates a negative pressure gradient relative to the liquid outlet port 51, which causes liquid dispensed from the liquid outlet port 51 to be atomized. The atomized liquid 54 is then carried by the gas flow from the gas outlet port 52 to the optical element 10, where the atomized liquid 54 flow deposits on the LED structure.

As further illustrated in FIG. 5, operations of the mass flow controllers 34A to 34D, the electronically controllable flow valve 40, and the gas pressurizer 42 can be controlled by a controller 20 via electronic control lines 22, 24, 26. The controller 20 can be a conventional programmable controller and/or can include an application specific integrated circuit (ASIC) configured to control operation of the respective elements of the system 100, or a general microprocessor or controller (e.g. computer).

Referring still to FIG. 5, by controlling the operations of the mass flow controllers (MFCs) 34A to 34D and the valve 40, the controller 20 can control the composition of liquid that is supplied to the spray nozzle 50 through the supply line 36. In particular, the controller 20 can cause the MFCs 30A, 30C and 30D to turn off, while the MFC 30B and the valve 40 are turned on, to thereby supply the binder liquid to the spray nozzle 50. Likewise, the controller 20 can cause the MFCs 30B, 30C and 30D to turn off, while the MFC 30A and the valve 40 are turned on, to thereby supply only the solvent liquid to the spray nozzle 50. With the solvent material from the solvent reservoir 30A flowing, the controller 20 can cause the MFCs 34C and/or 34D to release liquids bearing phosphor particles (in the case of the phosphor reservoir 30C) and/or diffuser particles (in the case of the diffuser reservoir 30D) into the flow in the supply line 36. Accordingly, the controller 20 can precisely control the composition of material sprayed onto the optical element 10 by the spray nozzle 50.

It will be appreciated that while FIG. 5 illustrates a single phosphor reservoir 30C and a single diffuser reservoir 30D, more reservoirs can be provided and attached to the supply line through respective MFCs and/or supply valves that can be electronically controlled by the controller 20. For example, separate phosphor reservoirs can be provided for red phosphors, green phosphors, yellow phosphors, blue phosphors, etc., depending on the product requirements. Some embodiments provide that more than one color of phosphor may be applied to an optical element 10 in respectively separate regions and/or mixed to form a single layer. Furthermore, more than one type of diffuser particle can be selectively provided using different diffuser reservoirs. For example, it may be desirable to apply diffuser particles having a first composition and/or diameter on one part of an optical element 10 and diffuser particles having a different composition and/or diameter on another part of the optical element 10. It may be desirable to apply more than one phosphor (e.g., different colors) in discrete areas of the LED structure. It may also be desirable to mix differently colored phosphors in a single layer, region and/or area of the LED structure (similar to FIG. 3, except different colored phosphors are within a single layer). In such cases, there may be at least two different phosphors applied at the same time, either from separate reservoirs or a single reservoir that contains multiple phosphors.

As illustrated, the heating device 37 applies heat 39 to the optical element 10 to increase the temperature of the optical element 10 prior to spraying the optical materials thereon. Some embodiments provide that the heating device may be electronically controlled by the controller 20 via electronic control line 29. In some embodiments, the heating device 37 may apply heat 39 to the optical element 10 during the spraying operation(s). In some embodiments, the heating device 37 may be used to heat the optical element 10 prior to the spraying operation(s) and/or may be operated independent of the controller 20.

Some embodiments provide that the heating device 37 includes a thermally conductive heating surface through which heat 39 is transferred to the optical element 10. In some embodiments, the heating device 37 may use a heat transfer media, such as, for example, heated air and/or gases, to transfer heat 39 to the optical element 10. Embodiments of the heating device may include electrically resistive and/or conductive and/or combustion related heat generating elements.

Some embodiments provide that the optical element 10 is heated to greater than 70 degrees Celsius. Some embodiments provide that the optical element 10 is heated to greater than 90 degrees Celsius. Some embodiments provide that the optical element 10 is heated to greater than 120 degrees Celsius. In some embodiments, the optical element 10 is heated to a temperature in a range of about 70 degrees Celsius to about 155 degrees Celsius. In some embodiments, the optical element 10 is heated to a temperature in a range of about 90 degrees Celsius to about 155 degrees Celsius. In some embodiments, the optical element 10 is heated to a temperature in a range of about 90 degrees Celsius to about 120 degrees Celsius. In some embodiments, the optical element 10 is heated to a temperature in a range of about 90 degrees Celsius to about 155 degrees Celsius. When the atomized liquid 54 is deposited on the optical element 10, the thermal energy in the heated optical element 10 rapidly cures and/or evaporates the solvent portion of the atomized liquid 54. By rapidly curing and/or evaporating the solvent, settling and/or redistribution of the optical materials prior to curing may be reduced. In this regard, a more uniform concentration of the optical materials within the applied layer may be preserved, thus providing a substantially conformal layer of optical materials on the LED structure.

It will be further appreciated that a system 100 as illustrated in FIG. 5 may be split into several parts, so that, for example, separate supply lines 36 are provided and/or separate spray nozzles 50 are provided. For example, a system could have a first supply line 36 and nozzle 50 dedicated to spray-applying an atomized liquid 54 from a first direction and/or at a first angle relative to the optical element 10 and a second supply line 36 and nozzle 50 dedicated to spray-applying an atomized liquid 54 from a second different direction and/or at a second different angle relative to the optical element 10. Some embodiments provide that the first and second supply lines 36 and nozzles 50 are configured to provide the same atomized liquids 54. In some embodiments, the first and second supply lines 36 and nozzles 50 are configured to provide different atomized liquids from one another. Accordingly, many different combinations of reservoirs, supply lines and spray nozzles are contemplated according to various embodiments.

A reservoir 41 may be provided to receive and mix supply line 36 constituents from various different ones of the reservoirs 30A-D. Fumed silica 37 may also be added to the reservoir 41.

In some embodiments, the reservoir 41 may include a static mixing element that causes the materials in the supply line 36 to mix by virtue of the flow therethrough. Some embodiments provide that may include an active mixing element that agitates the supply line 36 materials to keep particles in suspension and/or substantially uniformly distributed throughout the materials. In some embodiments, an active mixing element may be omitted to as to reduce agglomeration of fumed silica in the reservoir 41.

Although not illustrated, pressure controllers may be provided for various ones of the components. For example, the reservoirs 30A-D and the nozzles 50 may include pressure controllers to provide control over the supply and/or delivery pressures, among others. Further, some embodiments may include static and/or active mixing elements in the reservoirs 30A-D. For example, the phosphor reservoir 30C and the diffuser reservoir 30D may use mixing elements to maintain the particles in suspension.

FIG. 5 further illustrates an optical sensor 35 that is configured to sense light 37 emitted by the optical element 10. For example, the optical sensor 35 can detect a color point and/or intensity of light emitted by the optical element 10. The detected light information can be provided to the controller 30 via a communication line 28, and can be used as a feedback signal in the control of the operations of the deposition system 100, as described in more detail herein.

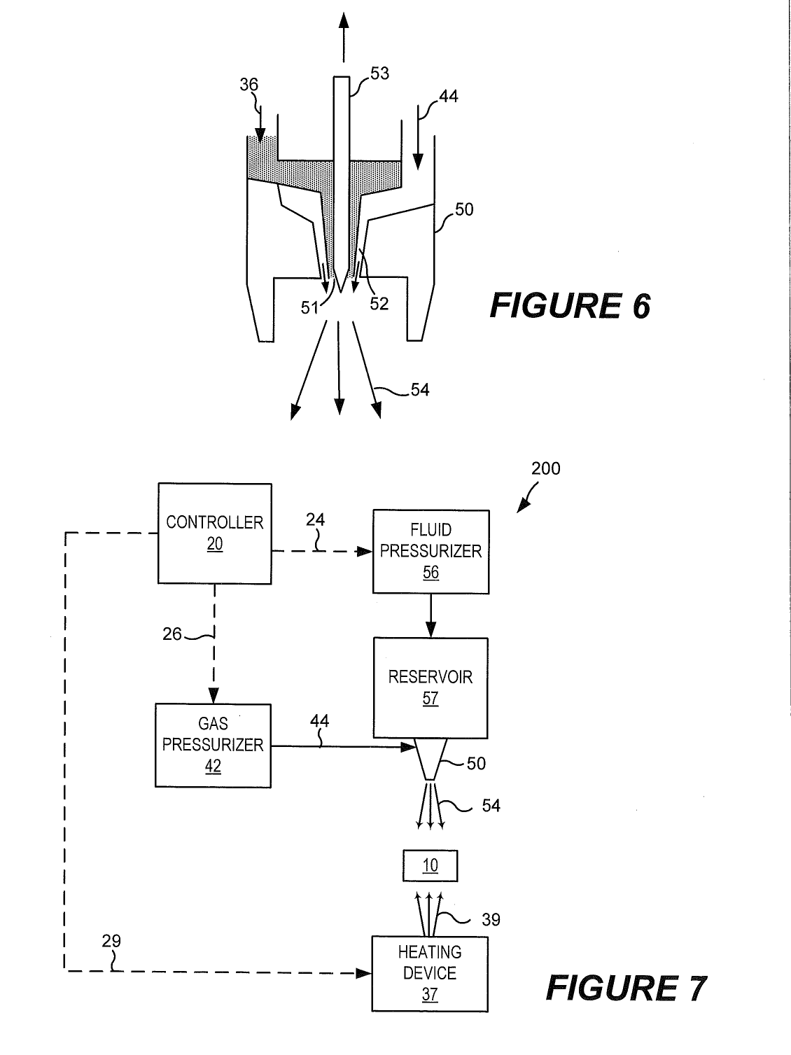

Reference is now made to FIG. 7, which is a schematic diagram illustrating a batch deposition system 200 for coating an optical element with optical materials, according to some embodiments of the invention. As discussed above regarding FIGS. 5 and 6, pressurized gas (e.g., pressurized air) generated by a gas pressurizer 42 may be supplied to the spray nozzle 50 through the pressurized gas supply line 44. The pressurized gas is directed to through a gas outlet port 52 in the spray nozzle 50 that is adjacent a liquid outlet port 51. The flow of liquid through the liquid outlet port 51 can be regulated, for example, by controlling the position of a retractable pin 53.

A syringe 57 may include a batch of optical materials 54. The optical materials 54 may include, for example, one or more types of phosphor particles, one or more types of diffuser particles, a binder, and/or one or more solvents. The syringe 57 may be loaded with a mixture, compound, solution and/or suspension including the optical materials using for example, a cartridge that is configured to contain the optical materials 54. In this manner, a batch of optical materials 54 may be prepared shortly before the application operations to reduce settling and/or stratification of the components therein. In some embodiments, the syringe may be coupled directly and/or closely to the nozzle 50 to reduce settling of suspended particles in the optical materials 54. Some embodiments provide that lateral fluid paths may be reduced and/or avoided as such paths may result in settling and/or stratification of the optical materials 54. In some embodiments, an active and/or static mixing element is provided with and/or within the syringe 57 to reduce settling.

A fluid pressurizer 56 may be provided to provide and/or control a fluid pressure within the syringe 57. Some embodiments provide that the fluid pressure may be substantially lower than the gas pressure provided by the gas pressurizer 42.

As further illustrated in FIG. 7, operations of the gas pressurizer 42, the fluid pressurizer 56 and the heating device 37 can be controlled by a controller 20 via electronic control lines 24, 26 and 29. The controller 20 can be a conventional programmable controller and/or can include an application specific integrated circuit (ASIC) configured to control operation of the respective elements of the system 200, or a general microprocessor or controller (e.g. computer).

Referring still to FIG. 7, by controlling the operations of the fluid pressurizer 56 and the gas pressurizer 42, the controller 20 can control the flow of liquid that is supplied to the spray nozzle 50.

It will be appreciated that while FIG. 7 illustrates a single syringe 57 and nozzle 50, more syringes 57 and nozzles 50 can be provided and attached to gas pressurizer 42 and the fluid pressurizer 56. In some embodiments, additional gas pressurizers 42 and fluid pressurizers 56 may be electronically controlled by the controller 20.

As illustrated, the heating device 37 applies heat 39 to the optical element 10 to increase the temperature of the optical element 10 prior to spraying the optical materials thereon. Some embodiments provide that the heating device may be electronically controlled by the controller 20 via electronic control line 29. In some embodiments, the heating device 37 may apply heat 39 to the optical element 10 during the spraying operation(s). In some embodiments, the heating device 37 may be used to heat the optical element 10 prior to the spraying operation(s) and/or may be operated independent of the controller 20.

Some embodiments provide that the heating device 37 includes a thermally conductive heating surface through which heat 39 is transferred to the optical element 10. In some embodiments, the heating device 37 may use a heat transfer media, such as, for example, heated air and/or gases, to transfer heat 39 to the optical element 10. Embodiments of the heating device may include electrically resistive and/or conductive and/or combustion related heat generating elements.

It will be further appreciated that a system 200 as illustrated in FIG. 7 may be split into several parts, so that, for example, separate syringes 57 are provided and/or separate spray nozzles 50 are provided. Accordingly, many different combinations of syringes 57, nozzles 50, fluid pressurizers 56 and/or gas pressurizers 42 are contemplated according to various embodiments.

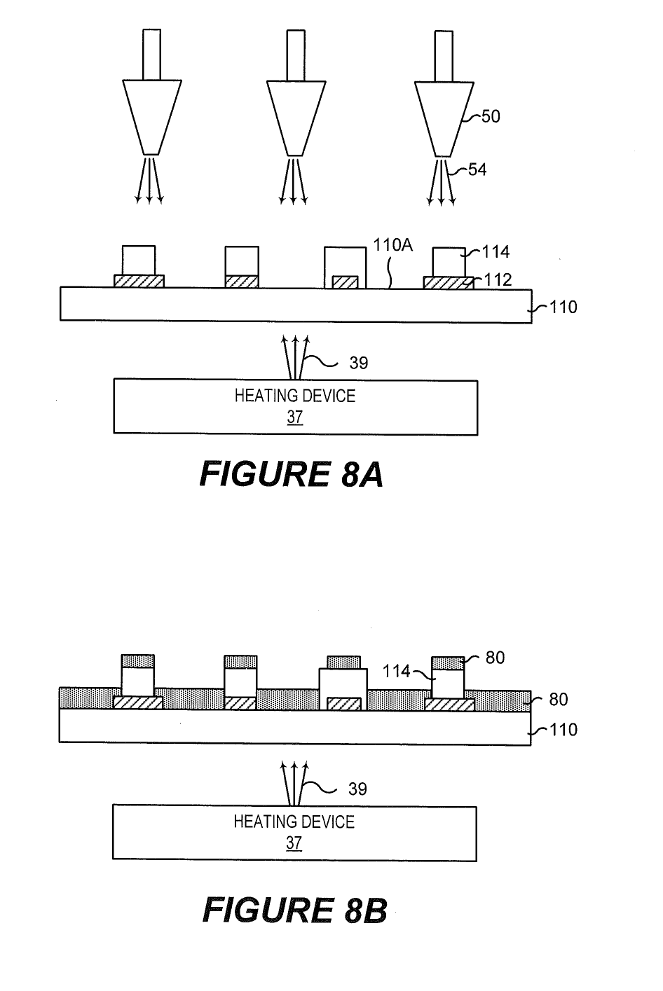

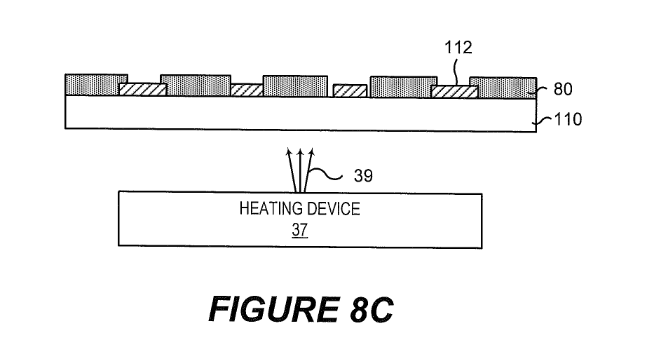

FIGS. 8A to 8C illustrate operations associated with coating an LED wafer according to some embodiments. Referring to FIG. 8A an LED wafer 110 is provided. As discussed above, an LED wafer includes a plurality of thin epitaxial layers that define a light emitting diode structure. The epitaxial layers are supported by a substrate that can include a growth substrate and/or a carrier substrate. The epitaxial region of the LED wafer 110 can be divided into a plurality of discrete device regions, for example, by mesa and/or implant isolation. In some embodiments, dicing streets (i.e. linear regions where the wafer is to be diced using a dicing saw) and/or scribe lines may already be formed in the LED wafer 110. A plurality of electrical contacts 112 are formed on the LED wafer 110. In particular, each discrete device in the LED wafer 110 can include at least one electrical contact 112 on a side of the wafer on which phosphor is to be applied.

A sacrificial pattern 114 is formed on the electrical contacts 112. The sacrificial pattern 114 can include a material such as soluble polymer and/or glass, which can be applied and patterned using conventional photolithographic techniques. The sacrificial pattern 114 can be aligned with the underlying electrical contacts 112. Alternatively, the sacrificial pattern 114 can cover only portions of the electrical contacts 112, with some portions of the electrical contacts 112 being exposed. In some embodiments, the sacrificial pattern 114 can be wider than the electrical contacts 112, so that portions of the surface 110A of the LED wafer 110 adjacent the electrical contacts are also covered by the sacrificial patterns. All three possibilities are illustrated in FIG. 8A.

Referring still to FIGS. 8A and 8B, the LED wafer 110 is heated using a heating device 37 and one or more conformal layers 80 of optical material, such as phosphor particles and/or diffuser particles, are applied to the surface 110A of the LED wafer 110 using a spray nozzle 50 of a pressurized deposition system 100 (FIGS. 1 and 2). The conformal layer 80 is coated onto the surface 110A of the LED wafer 110 and on the sacrificial pattern 114. In some embodiments, the layer 80 may also be coated onto upper portions of the electrical contacts 112 opposite the LED wafer 110.

After spray-coating the LED wafer 110, the sacrificial pattern 114 can be removed, for example, by exposure to a liquid solvent specific to the sacrificial pattern material, resulting in an LED wafer 110 as shown in FIG. 8C that includes exposed electrical contacts 112 and one or more layers 90 of optical material on the surface of the LED wafer 110. Although not specifically illustrated, some embodiments provide that the sacrificial pattern 114 may be formed using a film and/or tape that may be removed after the LED wafer is spray coated.

In the drawings and specification, there have been disclosed typical embodiments of the invention and, although specific terms are employed, they are used in a generic and descriptive sense only and not for purposes of limitation, the scope of the invention being set forth in the following claims.

1. A method, comprising:
providing an optical element;
providing a luminescent suspension comprising a liquid encapsulant material, phosphor particles, a solvent and a thixotropic agent;
atomizing the luminescent suspension; and
spraying the atomized luminescent suspension onto the optical element using a flow of pressurized gas.

2. The method of claim 1, wherein the thixotropic agent comprises fumed silica particles.

3. The method of claim 1, wherein the thixotropic agent comprises particles having a ratio of surface area per unit mass greater than about 100 m²/g.

4. The method of claim 1, wherein the thixotropic agent comprises particles having a concentration by weight to liquid encapsulant material in the luminescent suspension of less than about 1%.

5-7. (canceled)

8. The method of claim 1, wherein the phosphor particles comprise a first plurality of phosphor particles configured to convert incident light to light having a first dominant wavelength and a second plurality of phosphor particles configured to convert incident light to light having a second dominant wavelength that is different from the first dominant wavelength.

9. (canceled)

10. The method of claim 8, wherein the first phosphor particles have an average particle size that is smaller than an average particle size of the second phosphor particles.

11. The method of claim 1, wherein the thixotropic agent comprises agglomerated fumed silica particles having an average particle length between about 300 microns and 400 microns.

12. The method of claim 1, wherein spraying the luminescent suspension comprises spraying the luminescent suspension with an air pressurized spray system.

13-18. (canceled)

19. The method of claim 1, wherein the thixotropic agent comprises fumed alumina or fumed titania.

20. (canceled)

21. The method of claim 1, wherein the fumed silica particles comprise silicone treated fumed silica particles.

22. The method of claim 21, wherein the silicone treated fumed silica particles comprise silicone coated fumed silica particles.

23.-24. (canceled)

25. A light emitting structure, comprising:
an optical element having a plurality of surfaces and configured to emit light upon energization thereof; and
a phosphor layer comprising a thixotropic agent on the optical element, wherein the phosphor layer conforms to a shape of the optical element and has a thickness on each surface of the optical element on which it is formed of less than about 1000 microns.

26. The light emitting structure of claim 31, wherein the thixotropic agent comprises fumed silica particles.

27. The light emitting structure of claim 26, wherein the fumed silica particles comprise silicone treated filmed silica particles.

28. The light emitting structure of claim 27, wherein the silicone treated fumed silica particles comprise silicone coated fumed silica particles.

29. The light emitting structure of claim 25, wherein the thixotropic agent comprises particles having a ratio of surface area per unit mass greater than about 100 m²/g.

30. The light emitting structure of claim 25, wherein the thixotropic agent comprises agglomerated fumed silica particles having an average particle length between about 300 microns and 400 microns.

31.-36. (canceled)

37. The light emitting structure of claim 25, wherein the phosphor layer comprises a conformal layer on the optical element.

38. The light emitting structure of claim 25, wherein the phosphor layer has a thickness of less than 500 microns.

39. The light emitting structure of claim 25, wherein the phosphor layer has a thickness of less than 100 microns.
